(19) United States
(12) Patent Application Publication
(10) Pub. No.: US 2025/0045494 A1
(43) Pub. Date: Feb. 6, 2025

(54) SPATIALLY ARRANGED PROMPT VOLUMES TO GENERATE THREE-DIMENSIONAL DESIGNS

(71) Applicant: AUTODESK, INC., San Francisco, CA (US)

(72) Inventors: George William FITZMAURICE, Toronto (CA); Jo Karel VERMEULEN, East York (CA); Justin Frank MATEJKA, Newmarket (CA)

(21) Appl. No.: 18/649,872

(22) Filed: Apr. 29, 2024

Related U.S. Application Data
(60) Provisional application No. 63/516,670, filed on Jul. 31, 2023.
(60) Provisional application No. 63/519,802, filed on Aug. 15, 2023.

(51) Int. Cl. G06F 30/27

(52) U.S. Cl. CPC G06F 30/27

(57) ABSTRACT

In various embodiments, a computer-implemented method for generating a design object comprises generating a prompt within a design space generated by a design exploration application, wherein the prompt has a prompt definition that includes at least design intent text, and a prompt volume that occupies a portion of the design space and exerts a sphere of influence within the prompt volume, executing a trained machine learning (ML) model on the prompt to generate the design object, and displaying the design object within the prompt volume.

### CROSS-REFERENCE TO RELATED APPLICATIONS

This application claims priority benefit of the United States Provisional Patent Application titled “MULTI-MODALITY PROMPTS FOR ARTIFICIAL INTELLIGENCE MODELS,” filed on Jul. 31, 2023, and having Ser. No. 63/516,670, and “SPATIALLY ARRANGED AND AWARE OBJECTS THAT ARE DEFINED AND DRIVEN BY MULTI-MODAL PROMPTS,” filed on Aug. 15, 2023, and having Ser. No. 63/519,802. The subject matter of these related applications is hereby incorporated herein by reference.

### BACKGROUND

### Field of the Various Embodiments

The various embodiments relate generally to computer-aided design and artificial intelligence and, more specifically, to multimodal prompts for machine learning models to generate three-dimensional designs.

### Description of the Related Art

Design exploration for three-dimensional (3D) objects generally refers to a phase of a design process during which a designer generates and evaluates various design alternatives for one or more 3D objects within a larger 3D design project. As is well-understood in practice, manually generating multiple designs for even a relatively simple 3D object can be very labor-intensive and time-consuming. Because the time allocated for generating a design for a specific 3D object is usually limited, users typically produce only a small number of designs, which oftentimes reduces the overall quality of the final design. Accordingly, various conventional computer-aided design (CAD) applications have been developed that attempt to automate more fully how 3D objects are generated and evaluated.

One approach to automating how CAD applications generate and evaluate 3D objects involves implementing an artificial intelligence (AI) model, such as a generative machine learning model, to automatically synthesize a design in response to a prompt provided by the user. The prompt provided to the AI model is usually in the form of a design problem statement that specifies one or more design characteristics to which the generated design should adhere. The prompt can include any number of quantitative goals, physical objects, physical and functional constraints, and/or mechanical and geometric quantities that guide how the AI model should generate the design. The AI model responds to the prompt by executing various optimization algorithms to generate designs that satisfy the applicable design characteristics specified in the prompt. In some cases, the AI model generates a single design that the user selects and incorporates into the larger 3D design project. In other cases, the AI model generates numerous design alternatives and presents those design alternatives to a user within a design space. The user subsequently explores the design space, manually viewing and evaluating different design alternatives included in the design space in an attempt to select the best design alternative to incorporate into the larger 3D design project.

One drawback of the above approach is that conventional CAD applications typically do not limit the scope of designs generated by AI models. For example, a conventional CAD application may submit a prompt to an AI model to generate an object to be included as part of a larger 3D design. However, the AI model may respond not only by generating the object associated with the prompt, but also by modifying the overall geometry of the larger 3D design. As a result, a user typically has to fix the modified geometry manually, which can slow down the overall design process substantially.

Some conventional systems in a different technical area, such as two-dimensional (2D) image editors, include area tools and lasso tools that allow users to select a specific portion of an image that is to be modified. However, these types of tools can be used only with 2D images and cannot be readily extended to three-dimensional (3D) models. Further, conventional area tools and lasso tools can be used to modify only a single portion of an image at any given time. Consequently, users typically have to iteratively select and modify multiple different areas of an image in order to make all necessary modifications across the image, which can increase overall design time substantially.

As the foregoing illustrates, what is needed in the art are more effective techniques for automatically generating designs using artificial intelligence models.

### SUMMARY

In various embodiments, a computer-implemented method for generating a design object comprises generating a prompt within a design space generated by a design exploration application, wherein the prompt has a prompt definition that includes at least design intent text, and a prompt volume that occupies a portion of the design space and exerts a sphere of influence within the prompt volume, executing a trained machine learning (ML) model on the prompt to generate the design object, and displaying the design object within the prompt volume.

At least one technical advantage of the disclosed techniques relative to the prior art is that the disclosed techniques enable generative systems to modify portions of a larger 3D design with greater precision. In that regard, the disclosed techniques enable users to define spatial volumes within a design space that constrain the scope of the 3D objects generated by the generative design model. A design exploration application generating such spatial volumes within the larger design space enables a user to generate and modify specific aspects of a larger 3D design in a manner that ensures that the generative design model does not unintentionally modify other portions of the 3D design outside of the spatial volumes. Further, by using overlapping spatial volumes and/or a hierarchy of linked spatial volumes, the design exploration application enables users to modify multiple spatial volumes as a group in lieu of modifying each spatial volume separately, which reduces the overall design time for the user. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a system configured to implement one or more aspects of the various embodiments;

FIG. 2 is a more detailed illustration of the design exploration application of FIG. 1, according to various embodiments;

FIG. 3 is an exemplar illustration of the design space and the prompt space of FIG. 2, according to various embodiments;

FIG. 4 is an exemplar illustration of a hierarchy of prompt volumes, according to various embodiments;

FIG. 5 is an exemplar illustration of a weighted prompt volume, according to various embodiments;

FIG. 6 sets forth a flow diagram of method steps for generating prompt volumes within a prompt space, according to various embodiments; and

FIG. 7 depicts one architecture of a system within which embodiments of the present disclosure may be implemented.

### DETAILED DESCRIPTION

In the following description, numerous specific details are set forth to provide a more thorough understanding of the various embodiments. However, it will be apparent to one skilled in the art that the inventive concepts may be practiced without one or more of these specific details. For explanatory purposes, multiple instances of like objects are symbolized with reference numbers identifying the object and parenthetical numbers(s) identifying the instance where needed.

### System Overview

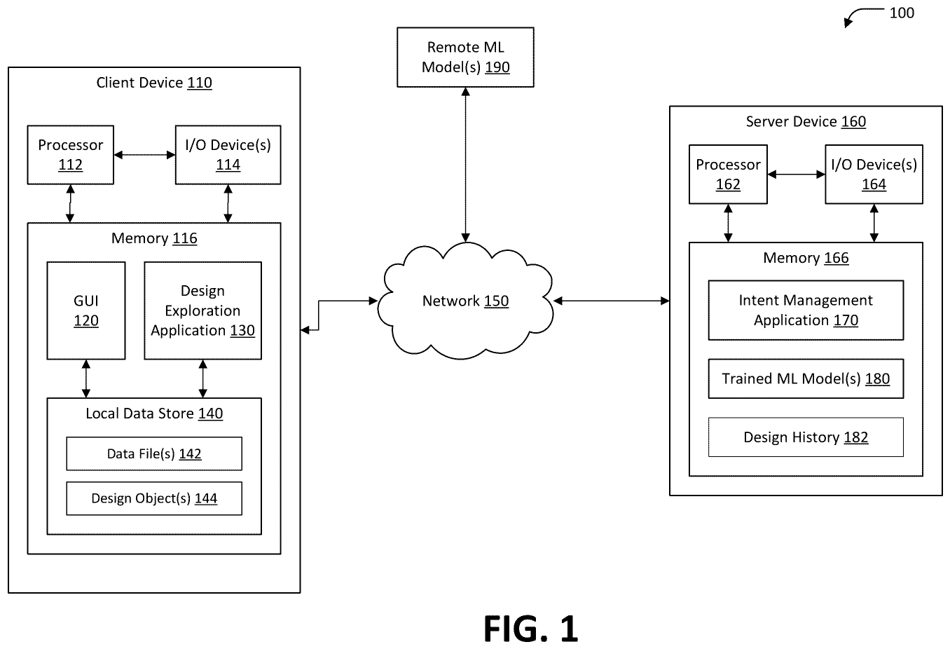

FIG. 1 is a conceptual illustration of a system 100 configured to implement one or more aspects of the various embodiments. As shown, in some embodiments, the system 100 includes, without limitation, a client device 110, a server device 160, and one or more remote machine learning (ML) models 190. The client device 110 includes, without limitation, a processor 112, one or more input/output (I/O) devices 114, and a memory 116. The memory 116 includes, without limitation, a graphical user interface (GUI) 120, a design exploration application 130, and a local data store 140. The local data store 140 includes, without limitation, one or more data files 142 and one or more design objects 144. The server device 160 includes, without limitation, a processor 162, one or more I/O devices 164, and a memory 166. The memory 166 includes, without limitation, an intent management application 170, one or more trained ML models 180, and design history 182. In some other embodiments, the system 100 can include any number and/or types of other client devices, server devices, remote ML models, or any combination thereof.

Any number of the components of the system 100 can be distributed across multiple geographic locations or implemented in one or more cloud computing environments (e.g., encapsulated shared resources, software, data) in any combination. In some embodiments, the client device 110 and/or zero or more other client devices (not shown) can be implemented as one or more compute instances in a cloud computing environment, implemented as part of any other distributed computing environment, or implemented in a stand-alone fashion. In various embodiments, the client device 110 can be integrated with any number and/or types of other devices (e.g., one or more other compute instances and/or a display device) into a user device. Some examples of user devices include, without limitation, desktop computers, laptops, smartphones, and tablets.

In general, the client device 110 is configured to implement one or more software applications. For explanatory purposes only, each software application is described as residing in the memory 116 of the client device 110 and executing on the processor 112 of the client device 110. In some embodiments, any number of instances of any number of software applications can reside in the memory 116 and any number of other memories associated with any number of other compute instances and execute on the processor 112 of the client device 110 and any number of other processors associated with any number of other compute instances in any combination. In the same or other embodiments, the functionality of any number of software applications can be distributed across any number of other software applications that reside in the memory 116 and any number of other memories associated with any number of other compute instances and execute on the processor 112 and any number of other processors associated with any number of other compute instances in any combination. Further, subsets of the functionality of multiple software applications can be consolidated into a single software application.

In particular, the client device 110 is configured to implement a design exploration application 130 to generate designs for one or more 3D objects. In operation, the design exploration application 130 causes one or more ML models 180, 190 to synthesize designs for a 3D object based on any number of goals and constraints. The design exploration application 130 then presents the designs as one or more design objects 144 to a user in the context of a design space. In some embodiments, the user can explore and modify the one or more design objects via the GUI 120. Additionally or alternatively, the user can also include at least one of the design objects 144 for use in additional design and/or manufacturing activities.

In various embodiments, the processor 112 can be any instruction execution system, apparatus, or device capable of executing instructions. For example, the processor 112 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 112 is a programmable processor that executes program instructions to manipulate input data. In some embodiments, the processor 112 can include any number of processing cores, memories, and other modules for facilitating program execution.

The input/output (I/O) devices 114 include devices configured to receive input, including, for example, a keyboard, a mouse, and so forth. In some embodiments, the I/O devices 114 also includes devices configured to provide output, including, for example, a display device, a speaker, and so forth. Additionally or alternatively, the I/O devices 114 may further include devices configured to both receive and provide input and output, respectively, including, for example, a touchscreen, a universal serial bus (USB) port, and so forth.

The memory 116 includes a memory module, or collection of memory modules. In some embodiments, the memory 116 can include a variety of computer-readable media selected for their size, relative performance, or other capabilities: volatile and/or non-volatile media, removable and/or non-removable media, etc. The memory 116 can include cache, random access memory (RAM), storage, etc. The memory 116 can include one or more discrete memory modules, such as dynamic RAM (DRAM) dual inline memory modules (DIMMs). Of course, various memory chips, bandwidths, and form factors may alternately be selected. The memory 116 stores content, such as software applications and data, for use by the processor 112. In some embodiments, a storage (not shown) supplements or replaces the memory 116. The storage can include any number and type of external memories that are accessible to the processor 112 of the client device 110. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 116 generally stores one or more application programs including the design exploration application 130, and data (e.g., the data files 142 and/or the design objects stored in the local data store 140) for processing by the processor 112. In various embodiments, the memory 116 can include non-volatile memory, such as optical drives, magnetic drives, flash drives, or other storage. In some embodiments, separate data stores, such as one or more external data stores connected via the network 150 (“cloud storage”) can supplement the memory 116. In various embodiments, the design exploration application 130 within the memory 116 can be executed by the processor 112 to implement the overall functionality of the client device 110 to coordinate the operation of the system 100 as a whole.

In various embodiments, the memory 116 can include one or more modules for performing various functions or techniques described herein. In some embodiments, one or more of the modules and/or applications included in the memory 116 may be implemented locally on the client device 110, and/or may be implemented via a cloud-based architecture. For example, any of the modules and/or applications included in the memory 116 could be executed on a remote device (e.g., smartphone, a server system, a cloud computing platform, etc.) that communicates with the client device 110 via a network interface or an I/O devices interface.

The design exploration application 130 resides in the memory 116 and executes on the processor 112 of the client device 110. The design exploration application 130 interacts with a user via the GUI 120. In some embodiments, the design exploration application 130 and one or more separate applications (not shown) interact with the same user via the GUI 120. In various embodiments, the design exploration application 130 operates as a 3D design application to generate and modify an overall 3D design that includes one or more design objects 144. The design exploration application 130 interacts with a user via the GUI 120 in order to generate the one or more design objects 144 via direct user input (e.g., one or more tools to generate 3D objects, wireframe geometries, meshes, etc.) or via separate devices (e.g., the trained ML models 180, the remote ML models 190, separate 3D design applications, etc.). When generating the one or more design objects 144 via separate devices, the design exploration application 130 generates a prompt that effectively describes design-related intentions using one or more modalities (e.g., text, speech, images, etc.). The design exploration application 130 then causes the one or more of the ML models 180, 190 to operate on the generated prompt to generate a relevant design object 144. The design exploration application 130 receives the design object 144 from the one or more ML models 180, 190 and displays the design object 144 within the GUI 120. The user can select via the GUI 120 the design object 144 for use, such as incorporating the design object 144 in a larger 3D design.

The GUI 120 can be any type of user interface that allows users to interact with one or more software applications via any number and/or types of GUI elements. The GUI 120 can be displayed in any technically feasible fashion on any number and/or types of stand-alone display device, any number and/or types of display screens that are integrated into any number and/or types of user devices, or any combination thereof. The design exploration application 130 can perform any number and/or types of operations to directly and/or indirectly display and monitor any number and/or types of interactive GUI elements and/or any number and/or types of non-interactive GUI elements within the GUI 120. In some embodiments, each interactive GUI element enables one or more types of user interactions that automatically trigger corresponding user events. Some examples of types of interactive GUI elements include, without limitation, scroll bars, buttons, text entry boxes, drop-down lists, and sliders. In some embodiments, the design exploration application 130 organizes GUI elements into one or more container GUI elements (e.g., panels and/or panes).

The local data store 140 is a part of storage in the client device 110 that stores one or more design objects 144 included in an overall 3D design and/or one or more data files 142 associated with 3D design. For example, an overall 3D design for a building can include multiple stored design objects 144, including design objects 144 separately representing doors, windows, fixtures, walls, appliances, and so forth. The local data store 140 can also include data files 142 relating to a generated overall 3D design (e.g., component files, metadata, etc.). Additionally or alternatively, the local data store 140 includes data files 142 related to generating prompts for transmission to the one or more ML models 180, 190. For example, the local data store 140 can store one or more data files 142 for sketches, geometries (e.g., wireframes, meshes, etc.), images, videos, application states (e.g., camera angles used within a design space, tools selected by a user, etc.), audio recordings, and so forth.

The design objects 144 include geometries, textures, images, and/or other components that the design exploration application 130 uses to generate an overall 3D design. In various embodiments, the geometry of a given design object refers to any multi-dimensional model of a physical structure, including CAD models, meshes, and point clouds, as well as circuit layouts, piping diagrams, free-body diagrams, and so forth. In some embodiments, the design exploration application 130 stores multiple design objects 144 for a given 3D design and stores multiple iterations of a given target object that the ML models 180, 190. For example, the user can form an initial prompt using the design exploration application 130 and receive a first generated design object 144(1) from the trained ML model 180(1), then refine the prompt and receive a second generated design object 144(2) from the trained ML model 180(1).

The network 150 can be any technically feasible set of interconnected communication links, including a local area network (LAN), wide area network (WAN), the World Wide Web, or the Internet, among others. The network 150 enables communications between the client device 110 and other devices in network 150 via wired and/or wireless communications protocols, including Bluetooth, Bluetooth low energy (BLE), wireless local area network (WiFi), cellular protocols, satellite networks, and/or near-field communications (NFC).

The server device 160 is configured to communicate with the design exploration application 130 to generate one or more design objects 144. In operation, the server device 160 executes the intent management application 170 to process a prompt generated by the design exploration application 130, select one or more ML models 180, 190 trained to generate design objects 144 in response to the contents of the prompt, and input the prompt into the selected ML models 180, 190. Once the selected ML models 180, 190 generate the design objects 144 that are responsive to the prompt, the server device 160 transmits the generated design objects to the client device 110, where the generated design objects 144 are usable by the design exploration application 130.

In various embodiments, the processor 162 can be any instruction execution system, apparatus, or device capable of executing instructions. For example, the processor 162 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 162 is a programmable processor that executes program instructions to manipulate input data. In some embodiments, the processor 162 can include any number of processing cores, memories, and other modules for facilitating program execution.

The input/output (I/O) devices 164 include devices configured to receive input, including, for example, a keyboard, a mouse, and so forth. In some embodiments, the I/O devices 164 also includes devices configured to provide output, including, for example, a display device, a speaker, and so forth. Additionally or alternatively, the I/O devices 164 may further include devices configured to both receive and provide input and output, respectively, including, for example, a touchscreen, a universal serial bus (USB) port, and so forth.

The memory 166 includes a memory module, or collection of memory modules. In some embodiments, the memory 166 can include a variety of computer-readable media selected for their size, relative performance, or other capabilities: volatile and/or non-volatile media, removable and/or non-removable media, etc. The memory 166 can include cache, random access memory (RAM), storage, etc. The memory 166 can include one or more discrete memory modules, such as dynamic RAM (DRAM) dual inline memory modules (DIMMs). Of course, various memory chips, bandwidths, and form factors may alternately be selected. The memory 166 stores content, such as software applications and data, for use by the processor 162. In some embodiments, a storage (not shown) supplements or replaces the memory 166. The storage can include any number and type of external memories that are accessible to the processor 162 of the server device 160. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 166 generally stores one or more application programs including the intent management application 170 and one or more trained ML models 180, and data (e.g., design history 182) for processing by the processor 112. In various embodiments, the memory 166 can include non-volatile memory, such as optical drives, magnetic drives, flash drives, or other storage. In some embodiments, separate data stores, such as one or more external data stores connected via the network 150 can supplement the memory 166. In various embodiments, the intent management application 170 and/or the one or more ML models 180 within the memory 166 can be executed by the processor 162 to implement the overall functionality of the server device 160 to coordinate the operation of the system 100 as a whole.

In various embodiments, the memory 166 can include one or more modules for performing various functions or techniques described herein. In some embodiments, one or more of the modules and/or applications included in the memory 166 may be implemented locally on the client device 110, server device 160, and/or may be implemented via a cloud-based architecture. For example, any of the modules and/or applications included in the memory 166 could be executed on a remote device (e.g., smartphone, a server system, a cloud computing platform, etc.) that communicates with the server device 160 via a network interface or an I/O devices interface. Additionally or alternatively, the intent management application 170 could be executed on the client device 110 and can communicate with the trained ML models 180 operating at the server device 160.

In various embodiments, the intent management application 170 receives a prompt from the design exploration application 130 and inputs the prompt into an applicable ML model 180, 190. In some embodiments, one or more of the ML models 180, 190 are trained to respond to specific types of inputs, such as a ML model that is trained to generate design objects from a specific combination of modalities (e.g., text and images). In such instances, the intent management application 170 processes a prompt to determine the modalities of the data that are included in the prompt and identifies one or more ML models 180, 190 that have been trained to respond to such a combination of modalities. Upon identifying the one or more ML models, the intent management application 170 selects an ML model (e.g., the trained ML model 180(1)) and inputs the prompt into the selected ML model 180(1).

The trained ML models 180 include one or more generative ML models that have been trained on a relatively large amount of existing data and optionally any number of results (e.g., design objects 144 and evaluations provided by the user) to perform any number and/or types of prediction tasks based on patterns detected in the existing data. In various embodiments, the remote ML models 190 are trained ML models that communicate with the server device 160 to receive prompts via the intent management application 170. In some embodiments, the trained ML model 180 is trained using various combinations of data from multiple modalities, such as textual data, image data, sound data, and so forth. The trained ML model 180 and/or the remote ML model 190 trained using at least two modalities of data are also referred to herein as a multimodal ML model. For example, in some embodiments, the one or more trained ML models 180 can include a third-generation Generative Pre-Trained Transformer (GPT-3) model, a specialized version of a GPT-3 model referred to as a “DALL-E2” model, a fourth-generation Generative Pre-Trained Transformer (GPT-4) model, and so forth. In various embodiments, the trained ML models 180 can be trained to generate design objects from various combinations of modalities. Such combinations include text, a CAD object, a geometry, an image, a sketch, a video, an application state, an audio recording, etc.).

The design history 182 includes data and metadata associated with the one or more trained ML models 180 and/or the one or more remote ML models 190 generating design objects 144 in response to prompts provided by the design exploration application 130. In some embodiments, the design history 182 includes successive iterations of design objects 144 that a single ML model 180 generates in response to a series of prompts. Additionally or alternatively, the design history 182 includes multiple design objects 144 that were generated by different ML models 180, 190 in response to the same prompt. In some embodiments, the design history 182 includes feedback provided by the user for a given design object 144. In such instances, the server device 160 can use the design history 182 as training data to further train the one or more ML models 180. Additionally or alternatively, the design exploration application 130 can retrieve contents of the design history 182 and display the retrieved contents to the user via the GUI 120.

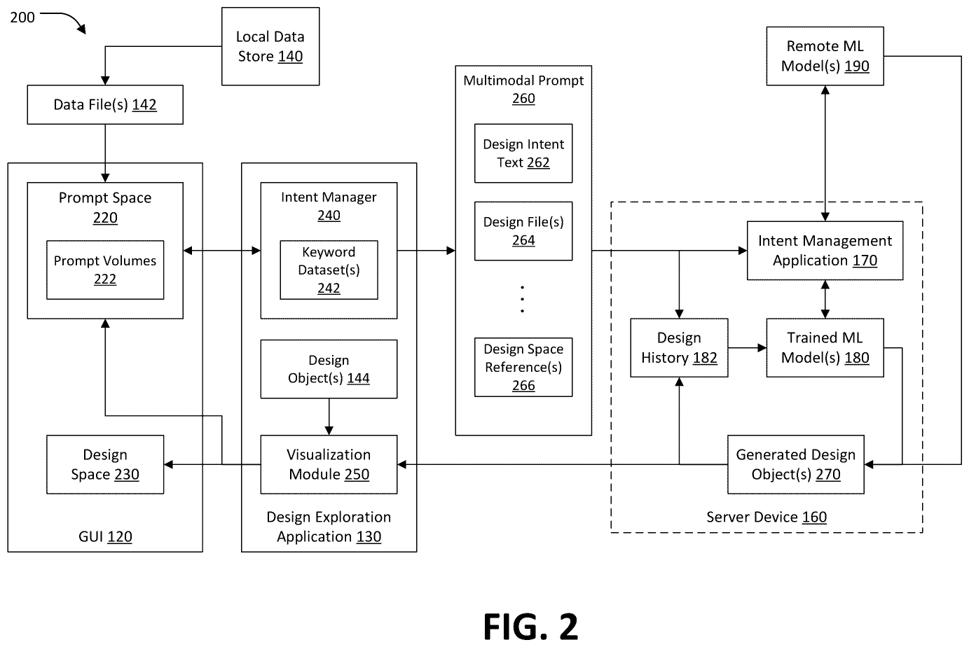

FIG. 2 is a more detailed illustration of the design exploration application 130 of FIG. 1, according to various embodiments. As shown, in some embodiments, the system 200 includes, without limitation, the GUI 120, the design exploration application 130, local data store 140, the one or more data files 142, the server device 160, the remote ML models 190, and a multimodal prompt 260. The GUI 120 includes, without limitation, a prompt space 220 including one or more prompt volumes 222, and a design space 230. The design exploration application 130 includes, without limitation, an intent manager 240 including one or more keyword datasets 242, the one or more design objects 144, and a visualization module 250. The server device 160 includes, without limitation, the intent management application 170, the one or more trained models 180, the design history 182, and one or more generated design objects 270. The multimodal prompt 260 includes, without limitation, design intent text 262, one or more design files 264, and one or more design space references 266.

For explanatory purposes only, the functionality of the design exploration application 130 is described herein in the context of exemplar interactive and linear workflows used to generate the generated design object 270 in accordance with user-based design-related intentions expressed during the workflow. The generated design object 270 includes, without limitation, one or more images, wireframe models, geometries, and/or meshes for use in a three-dimensional design, as well as any amount (including none) and/or types of associated metadata.

As persons skilled in the art will recognize, the techniques described herein are illustrative rather than restrictive and can be altered and applied in other contexts without departing from the broader spirit and scope of the inventive concepts described herein. For example, the techniques described herein can be modified and applied to generate any number of generated design objects 270 associated with any target 3D object in a linear fashion, a nonlinear fashion, an iterative fashion, a non-iterative fashion, a recursive fashion, a non-recursive fashion, or any combination thereof during an overall process for generating and evaluating designs for that target 3D object. A target 3D object can include any number (including one) and/or types of target 3D objects and/or target 3D object components.

For example, in some embodiments, a generated design object 270 can be generated and displayed within the GUI 120 during a first iteration, any portion (including all) of the design object 270 can be selected via the GUI 120, and a first prompt multimodal prompt 260 can be set equal to the selected portion of the generated design object 270 to recursively generate a second generated design object 270 during a second iteration. In the same or other embodiments, the design exploration application 130 can display and/or re-display any number of GUI elements, generate and/or regenerate any amount of data, or any combination thereof any number of times and/in any order while generating each new generated design object 270.

In operation, the visualization module 250 of the design exploration application 130 provides the prompt space 220 and the design space 230 via the GUI 120. A user provides the contents for the multimodal prompt 260 via the prompt space 220. The design exploration application 130 processes the content to generate the multimodal prompt 260 and transmits the multimodal prompt 260 to the server device 160. The intent management application 170 identifies the modalities of the data included in the multimodal prompt 260 and identifies one or more trained ML models 180 and/or remote ML models 190 that have been trained to process the identified combination of modalities. The intent management application 170 inputs the multimodal prompt into one or more of the identified ML models 180, 190. The ML models 180, 190 respond to the multimodal prompt 260 by generating one or more design objects 270. The visualization module 250 receives the one or more generated design objects 270 and displays the one or more generated design objects 270 in the prompt space 220 and/or the design space 230.

In various embodiments, the design space 230 is a virtual workspace that includes one or more renderings of design objects (e.g., geometries of the design objects 144 and/or the generated design objects 270) that form an overall 3D design. In some embodiments, the design space includes multiple design alternatives for the overall 3D design. For example, the design space 230 may graphically organize multiple 3D designs that include differing combinations of design objects 144, 270. In such instances, the user interacts with the GUI to navigate between design alternatives to quickly analyze tradeoffs between different design options, observe trends in design options, constrain the design space, select specific design options, and so forth.

The prompt space 220 is panel or volume in which a user can generate prompts, such as the multimodal prompt 260 and/or the one or more prompt volumes 222. In some embodiments, the prompt space is a panel, such as a window separate from the design space. Alternatively, in some embodiments, the prompt space 220 is a volume that is overlayed over at least a portion of the design space. In such instances, a user can invoke a prompt volume 222 and/or an input area for a multimodal prompt 260 at various locations within the design space 230.

The prompt volume 222 is a form of a prompt that executes operations within the boundaries of the volume. The prompt volume 222 is a volume within the design space that is defined by a corresponding prompt definition that specifies how objects appear and/or behave within the boundaries of the prompt volume 222. The prompt volume 222 exerts a “sphere of influence” (e.g., a volume of influence based on the boundaries) within the defined boundaries such that modifications made to the associated prompt definition causes changes to design objects within the boundaries. For example, the prompt definition enables the user to specify design intent text and/or non-textual inputs for objects that at least partially overlap the prompt volume 222. The prompt volume 222 a set of characteristics, including a spatial position (e.g., location and orientation), boundaries (defined via the textual definition or via user input within the prompt space 220), and shape (e.g., a sphere, a cuboid, a pyramid, an irregular 3D shape, etc.). In some embodiments, the prompt volume 222 includes weighted areas, weighted gradients, and/or linked prompt volumes (e.g., prompt volumes 222(1)-222(x)). In such instances, the linked prompted volumes include other overlapping prompt volumes and/or other prompt volumes linked in a hierarchy.

In various embodiments, when the user modifies the prompt volume 222, the prompt volume executes by updating one or more design objects 144, 270 that are within the sphere of influence of the prompt volume 222. For example, upon detecting a change to the prompt definition, the prompt volume 222 can receive a newly generated design object 270 and replace an existing design object 144 that is within the prompt volume 222. Upon executing the updates, the prompt volume 222 can cause the design exploration application 130 to generate a message indicating the change and “transmit” the message to other linked prompt volumes 222. In such instances, the prompt volumes 222 propagate changes among linked prompt volumes 222, which enables users to make modifications to multiple volumes within the design space 230 without applying global changes to the entire design space 230.

In various embodiments, the intent manager 240 determines the intent of inputs provided by the user. For example, the intent manager 240 can comprise a natural language (NL) processor that parses text provided by the user. Additionally or alternatively, the intent manager 240 can process audio data to identify words included in audio data and parse the identified words. In various embodiments, the intent manager 240 identifies one or more keywords in textual data. In some embodiments, the intent manager 240 includes one or more keyword datasets 242 that the intent manager 240 references when identifying the one or more keywords included in textual data. For example, the keyword datasets 242 can include, without limitation, a 3D keyword dataset that includes any number and/or types of 3D keywords, a customized keyword dataset that includes any number and/or types of customized keywords, and/or a user keyword dataset that includes any number and/or types of user keywords (e.g., words and/or phrases specified by a user).

The keywords can comprise particular words or phrases (e.g., demonstrative pronouns, technical terms, referential terms, etc.) that are relevant to designing 3D objects. For example, a user can input a regular sentence (“I want a hinge to connect here”) within an input area within the prompt space 220. The intent manager identifies “hinge,” “connect,” and “here” as words relevant to the ML model 180, 190 generating a design object 270. In such instances, the intent manager 240 can update the prompt space 220 by highlighting the keywords, enabling the user to provide additional details (e.g., non-textual data) for inclusion in the multimodal prompt 260.

In various embodiments, the visualization module 250 displays the design space 230 and/or the prompt space 220 via the GUI 120. In some embodiments, the visualization module 250 updates the prompt space 220 and/or the design space 230 based on inputs by the user and/or data received from the server device 160. For example, the visualization module 250 can initially respond to the user invoking a prompt via a hotkey or a marking menu within the prompt space by displaying an input area to receive data to include in the multimodal prompt 260. When the user initially inputs a textual phrase, the visualization module 250 can respond to the intent manager 240 identifying one or more keywords by updating the input area highlight the keywords and/or display contextual input areas proximate to at least one keyword. In this manner, the design exploration application 130 iteratively receives multiple modalities of input data to include into the multimodal prompt 260.

In various embodiments, the design exploration application 130 receives textual and/or non-textual data to include in the multimodal prompt via the input areas included in the prompt space. When providing non-textual data, the user can retrieve stored data, such as one or more stored data files 142 (e.g., stored geometries, stored CAD files, audio recordings, stored sketches, etc.) from the local data store 140. Additionally or alternatively, the user can retrieve contents from the design history 182 and can add the contents into the input area. In such instances, the contents from the design history 182 is stored in one or more data files 142 that the user retrieves from the local data store 140.

The multimodal prompt 260 is a prompt that includes two or more modalities of data (e.g., textual data, image data, audio data, etc.) that specifies the design intent of the user. In various embodiments, the design exploration application 130 receives multiple types of data and builds the multimodal prompt 260 to include each of the multiple types of data. For example, a user can initially write design intent text 262 that refers to a sketch. The design exploration application 130 then receives a sketch (e.g., a stored sketch or a sketch the user inputs into an input design area). Upon receiving the sketch, the design exploration application 130 can then generate the multimodal prompt 260 to include both the design intent text 262 and the sketch. In some embodiments, the multimodal prompt 260 can include multiple data inputs of the same modality. For example, the multimodal prompt 260 can include multiple design intent texts 262 (e.g., 262(1), 262(2), etc.) and/or multiple design files 264 (e.g., 264(1), 264(2), etc.).

The design intent text 262 includes textual data that describes the intent of the user. For example, the design intent text can include descriptions for characteristics of a target 3D design object (e.g., a handle made of titanium”). In some embodiments, the design exploration application 130 generates design intent text from a different type of data input. For example, the intent manager 240 can perform NL processing to identify words included in an audio recording. In such instances, the design exploration application 130 generates design intent text 262 that includes the identified words.

The design files 264 includes one or more files (e.g., CAD files, stored text, audio recordings, stored geometries, etc.) that the user adds to be included in the multimodal prompt 260. In some embodiments, the design files 264 can include textual data (e.g., textual descriptions, physical dimensions, etc.). In various embodiments, a user can add multiple design files 264 to include in the multimodal prompt 260. In some embodiments, the design exploration application 130 converts various types of data into the design files 264. For example, the user can record audio via the input area. In such instances, the design exploration application 130 can store audio recording as a design file 264. The design files 264 can include one or more modalities (e.g., textual data, video data, audio data, image data, etc.).

In some embodiments, the design space references 266 can include one or more references to the prompt space 220 and/or the design space 230. For example, the user can input text that references a specific application state (e.g., “make the thing selected by the current tool lighter,” “generate a seat for the car in this view,” etc.). In such instances, the design exploration application 130 determines the application state the user is referencing. The design exploration application 130 can then include the reference in the multimodal prompt 260 as the design space reference 266.

In various embodiments, the intent management application 170 receives and processes the multimodal prompt 260 to identify the modalities of the contents of the multimodal prompt 260. For example, the intent management application 170 the modalities of the design intent text 262, the one or more design files 264, and/or the one or more design space references 266 included in the multimodal prompt 260. For example, the intent management application 170 can identify a combination of text, image, and video modalities included in the multimodal prompt. The intent management application 170 identifies at least one ML model 180, 190 that was trained with that combination of modalities and selects one of the identified ML models 180, 190. The intent management application 170 executes the selected ML model by inputting the multimodal prompt 260 into the selected ML model. The selected ML model generates a design object 270 in response to the multimodal prompt 260. In some embodiments, the server device includes the generated design object 270 in the design history 182. In such instances, the generated design object 270 is a portion of the design history 182 used as training data to train one or more trained ML models 180 (e.g., further training the selected ML model, training other ML models, etc.).

### Spatially Arranged Prompt Volumes to Generate Three-Dimensional Designs

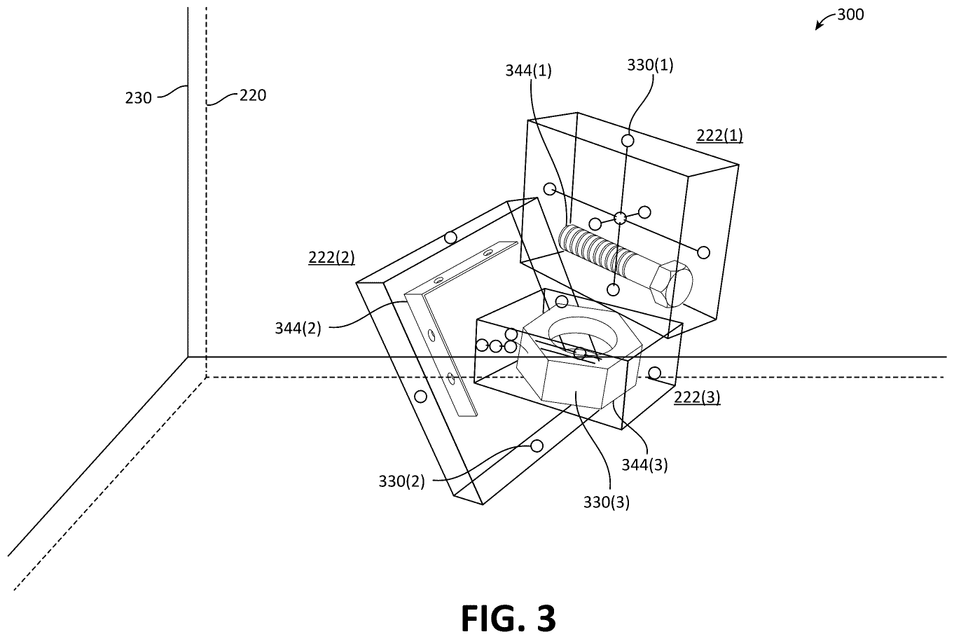

FIG. 3 is an exemplar illustration of the design space 230 and the prompt space 220 of FIG. 2, according to various embodiments. As shown, the visualization 300 includes, without limitation, the prompt space 220, the design space 230, a plurality of prompt volumes 222 (e.g., 222(1), 222(2), etc.), a plurality of prompt volume boundaries 330 (e.g., 330(1), 330(2), etc.), and a plurality of geometries 344 (e.g., 344(1), 344(2)) of a plurality of design objects 144.

In various embodiments, the visualization module 250 of the design exploration application 130 displays a visualization 300 of the design space 230 and the prompt space 220 via the GUI 120. As shown, the visualization displays a unified prompt space, where the prompt space 220 is overlayed over the design space 230. In such instances, the user can invoke a prompt anywhere within the design space 230.

The design space 230 is a volume that displays one or more geometries 344 of design objects 144 that are part of a 3D design. The design space 230 can include two-dimensional (e.g., panels, textures, overlays, etc.) and/or three-dimensional content. In various embodiments, the design exploration application 130 enables the user to manipulate a camera within the design space 230 using one or more tools (not shown) to control the roll, pitch, yaw, zoom level, etc., of the camera. Additionally or alternatively, the design exploration application 130 includes controls to sketch images, create new geometries 344 and textures and/or edit existing geometries 344 of design objects 144. In various embodiments, the design space 230 can include multiple geometries 344 that combine to form an overall 3D design. For example, the plurality of geometries 344(1)-344(3) can be included in an overall 3D design.

The prompt space 220 is a volume that overlays at least a portion of the design space 230. In various embodiments, the user can invoke a prompt (e.g., a prompt volume 222 or a prompt input area) via a hotkey or a marketing menu within the prompt space 220. For example, the user can select a tool (not shown) to draw one or more of the prompt volumes 222. Additionally or alternatively, in some embodiments, the user can press a hotkey to invoke the one or more of the prompt volumes 222. In some embodiments, the prompt space can include a prompt input area where the user can add textual data to specify portions of a prompt definition for the corresponding prompt volume 222.

The prompt boundaries 330 define the volume within the design space 230. The prompt definition that specifies how objects appear and/or behave within the particular prompt boundaries 330. Additionally or alternatively, prompt definition defines the characteristics of the sphere of influence within the prompt boundaries 330. In various embodiments, the prompt volumes 222 operate and execute such that modifications made to the associated prompt definition causes changes to the geometries 344 within the prompt boundaries 330. For example, the prompt definition can define characteristics for one or more objects (e.g., a screw) within the prompt boundary 330(1). The prompt volume 222 operates by causing the trained ML model 180 to generate a design object 270 having a geometry 344(1). In such instances, changes to the prompt definition causes the prompt volume 222 to update the object, causing the trained ML model 180 to generate a new design object 270 having a new geometry (not shown) to replace the geometry 344(1).

In some embodiments, the prompt boundaries 330 have coordinates that define the spatial position (e.g., location and orientation), and shape (e.g., a sphere, a cuboid, a pyramid, an irregular 3D shape, etc.) of the prompt volume 222. In some embodiments, the prompt volume 222 includes weighted areas and weighted gradients in portions of the prompt volume 222. For example, the prompt boundary 330(2) can include one or more weighted values and/or gradients that emphasize one group of characteristics (e.g., lighter materials, less density, etc.) closer to the middle of the prompt boundaries 330(2) and emphasize a different group of characteristics (e.g., cheaper materials, higher strength, etc.) closers to the edges of the prompt boundaries 330(3).

In various embodiments, a single prompt volume 222 can be linked to one or more other prompt volumes, where the linked prompt volumes are within the sphere of influence of the single prompt volume 222. The linked prompt volumes include other overlapping prompt volumes and/or other prompt volumes linked in a hierarchy. In such instances, updates to the prompt volume 222 causes the prompt volume to propagate changes by transmitting messages indicating the changes to the linked prompt volumes 222. The linked prompt volumes respond by performing updates based on the indication and transmitting messages indicating the updates to other prompt volumes that are within the sphere of influence of the linked prompt volumes 222. In this manner, a user can apply changes to a plurality of prompt volumes 222 by modifying a single prompt definition.

For example, the prompt volume 222(2) overlaps with the prompt volumes 222(1) and 222(3). The prompt volumes 222(1) and 222(3) are thus within the sphere of influence of the prompt volume 222(2). When the user modifies the prompt definition for the prompt volume 222(2), the prompt volume operates by updating the design objects 144 (e.g., the design object 144(2)) that has the geometry 344(2) within the sphere of influence of the prompt volume 222(2). The prompt volume 222 can receive a newly generated design object 270 having a new geometry (not shown), and replace the existing geometry 344(2) with the newly generated design object 270. Upon executing the updates, the prompt volume 222(2) can cause the design exploration application 130 to generate a message indicating the change and “transmit” the message to other linked prompt volumes 222(1), 222(3). In some embodiments, the prompt volumes 222 operate on an execution cycle. In such instances, a given prompt volume 222 receives a message indicating a change during one cycle and propagates the message during a subsequent cycle.

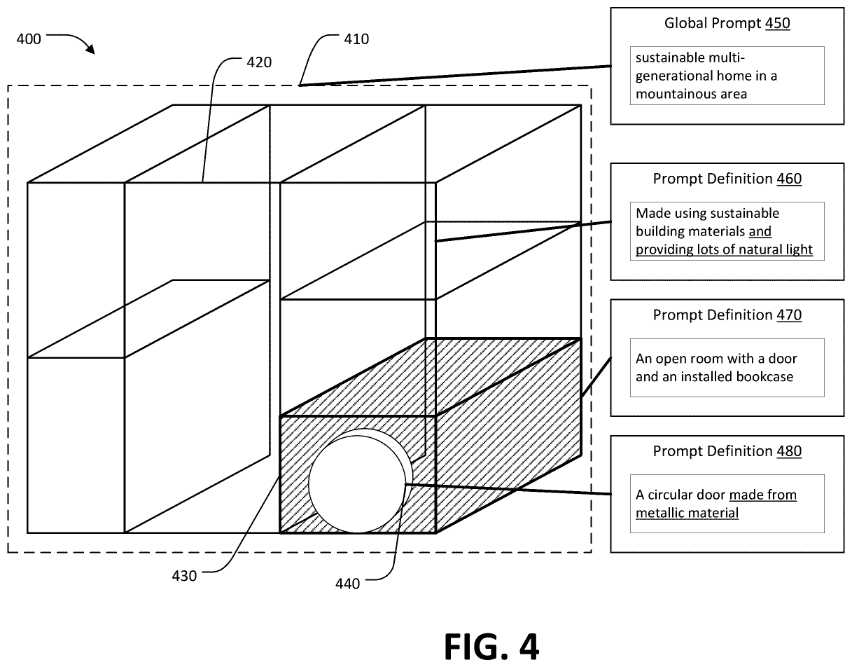

FIG. 4 is an exemplar illustration of a hierarchy of prompt volumes 410-434, according to various embodiments. As shown, the visualization 400 includes, without limitation, an overall design 410, prompt volumes 420-440, a global prompt 450 and prompt definitions 460-480.

In operation, the user may describe an overarching goal for the overall design 410 via the global prompt 450. The user can also generate a set of nested prompt volumes 420-440 within the overall design 410 that are linked in a hierarchical relationship. Each prompt volume 420-440 has a corresponding prompt definition 460-470 that includes a descriptive design goal for the respective prompt volumes 420-440. The design exploration application 130 forms multimodal prompts 260 for each of the respective prompt definitions 460-480 and transmits the multimodal prompts 260 to one or more ML models 180, 190 to generate design objects 270 to include in the respective prompt volumes 420-440. When the user changes the content of one of the prompt definitions 460-480, the design exploration application 130 causes the corresponding prompt volume to update and propagates the change to the other prompt volumes 420-440 in the hierarchy. In various embodiments, two or more of the prompt volumes 420-440 can operate in parallel. Additionally or alternatively, two or more of the prompt volumes 420-440 can execute separate ML models 180, 190 to generate the design objects 270 that are responsive to the respective prompt definitions 460-480.

For example, a user can specify the global prompt 450 for the overall design 410 (e.g., a sustainable building) within the design space 230. The user can also specify a hierarchy of prompt volumes 420-440, such as a first level prompt volume 420 that controls design objects for the building, a second level prompt volume 430 that controls design objects for a room, and a third level prompt volume 440 that controls design objects for a particular fixture (e.g., a door). The user can initially specify characteristics for design objects within the respective prompt volumes 420-440 via the prompt definitions 460-480. When the user makes a change (e.g., adding “providing lots of natural light”) to the prompt definition 460 for the prompt volume 420, the design exploration application 130 responds by transmitting a new multimodal prompt 260 to the ML model 180, 190 to generate updated design objects 270 that adhere to the updated design goal. The design exploration application 130 then causes the prompt volume 420 to update with the updated design objects 270. The design exploration application 130 can iteratively also identify the prompt volumes 430-440 as linked in the hierarchy and causes the prompt volumes 430-440. to update,

In some embodiments, changes to a nested prompt volume 440 does not trigger changes to prompt volumes 420-430 higher in the hierarchy. For example, the design exploration application 130 can respond to a change in the prompt definition 480 by causing the prompt volume 440 to update the design objects 144 within the prompt volume 440. Upon updating the prompt volume 440, the design exploration application 130 can determine that the prompt volumes 420-430 are not within the sphere of influence of the prompt volume 440 and can refrain from successively updating the prompt volumes 420-440.

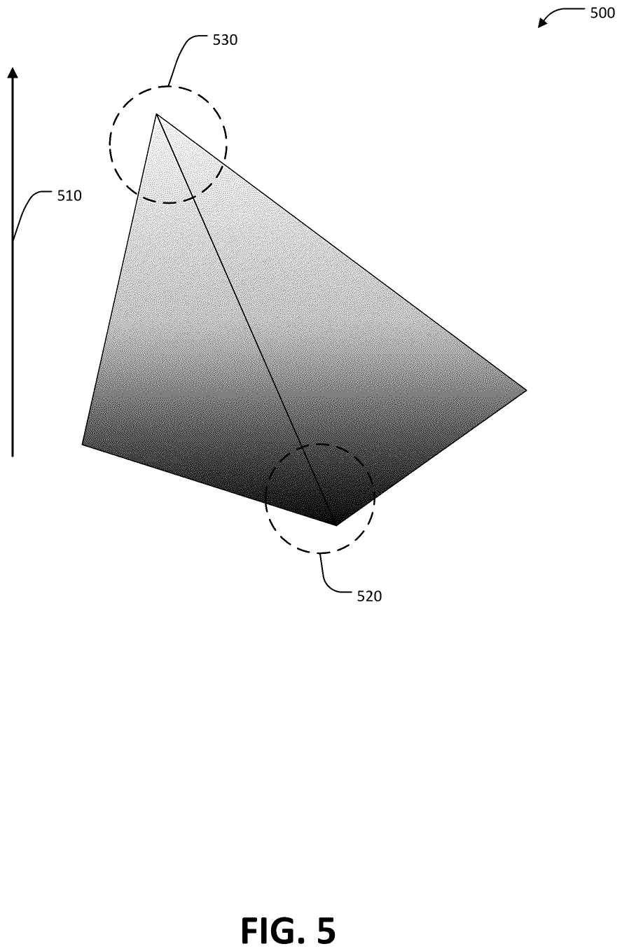

FIG. 5 is an exemplar illustration of a weighted prompt volume 500, according to various embodiments. As shown, the weighted prompt volume 500 includes, without limitation, a first weighted portion 520 and a second weighted portion 530. In various embodiments, the weighted prompt volume 500 has a configurable sphere of interest. For example, the weighted prompt volume 500 can adhere to a weighted gradient 510 that emphasizes a characteristic (e.g., density) closer to the middle based the weighted prompt volume 500. As a result, multimodal prompts 260 for the weighted prompt volume 500 causes the ML model 180, 190 to generate design objects 270 with greater density at the first weighted portion 520 and lower density at the second weighted portion 530. In this manner, the sphere of influence for the weighted prompt volume 500 to produce high-density design objects 270 gradually trails off along the weighted gradient 510.

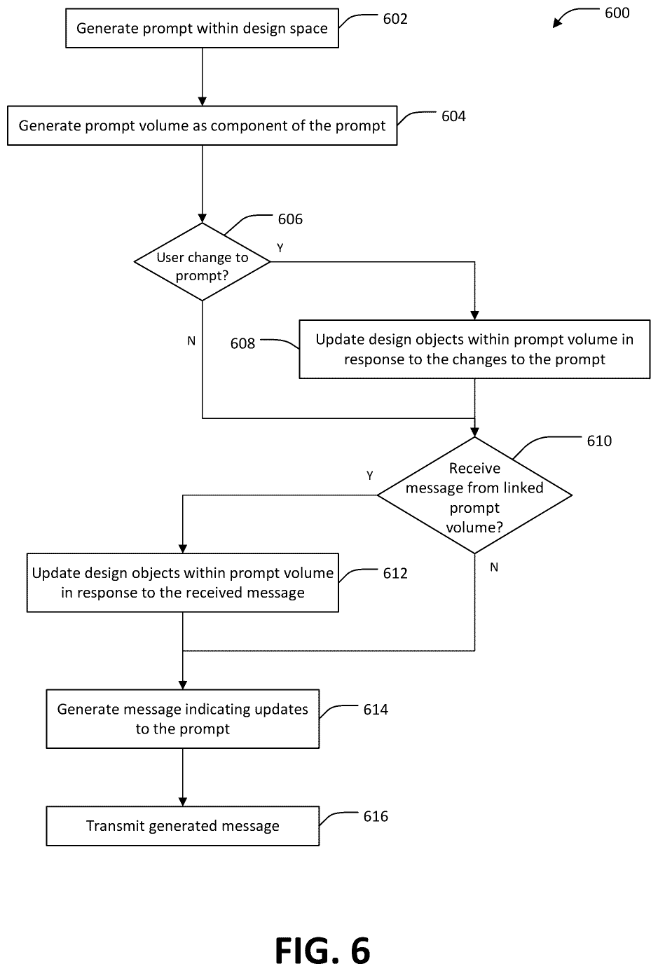

FIG. 6 sets forth a flow diagram of method steps for generating prompt volumes within a prompt space, according to various embodiments. Although the method steps are described with reference to the systems of FIGS. 1-5, persons skilled in the art will understand that any system configured to implement the method steps, in any order, falls within the scope of the embodiments.

As shown, a method 600 begins at step 602, where the design exploration application 130 generates a prompt within the design space 230. In various embodiments, the design exploration application 130 can display a unified prompt space for a user to generate a prompt that includes a prompt definition and prompt volume 222. In such instances, the prompt space 220 overlaps the design space 230 and a user can invoke a prompt anywhere in the design space. The design exploration application responds to a user input by generating a prompt.

At step 604, the design exploration application 130 generates a prompt volume 222 as a component of the prompt. In various embodiments, the design exploration application 130 generates a prompt volume 222 within the design space that adheres to an appearance and behavior specified by a corresponding prompt definition. The prompt definition enables a user to specify design intent text and/or non-textual inputs. The prompt volume 222 has a spatial position and a set of prompt boundaries 330 that are defined via the textual definition, or via user input within the design space 230. The prompt volume 222 includes a set of characteristics, including shape (e.g., spheres, cuboids, pyramids, irregular 3D shapes, etc.), weighted portions 520, 530, weighted gradients 510, and linked prompt volumes 222. The prompt volume exerts a sphere of influence within the defined boundaries such that modifications made to the associated prompt definition causes changes to design objects within the boundaries.

At step 606, the design exploration application 130 determines whether the user has made any changes to the prompt. In various embodiments, upon generating the prompt, the design exploration application 130 waits for user to make changes to the prompt definition or directly to the prompt volume 222 (e.g., move, rotate, and/or scale the prompt volume 222, change the shape of the prompt volume 222, etc.). In various embodiments, the prompt volume 222 has an execution loop to execute operations, such as updates to the design objects 144. In such instances, the design exploration application 130 waits determines whether a user input provided an input that caused a change. When the design exploration application 130 detects a user change, the design exploration application 130 proceeds to step 608; otherwise, the design exploration application 130 does not detect a user change and proceeds to step 610.

At step 608, the design exploration application 130 updates design objects 144 within the prompt volume 222 in response to the user changes to the prompt. In various embodiments, upon identifying a user input that changes to the prompt definition or prompt volume, the design exploration application 130 responds by updating one or more design objects 144 that are within the prompt volume. In some embodiments, the design exploration application 130 performs the update by transmitting a new multimodal prompt 260 based on the user changes. In such instances, the design exploration application 130 executes the applicable generative ML model 180, 190 on the multimodal prompt 260 to generate one or more updated design objects 270. The design exploration application 130 receives the updated design objects 270 and causes the prompt volume 222 to update by replacing the existing design object 144 with the updated design object 270.

At step 610, the design exploration application 130 determines whether the prompt volume 222 receives a message from a linked prompt volume. In various embodiments, the design exploration application 130 tracks each prompt volume 222 that transmits a message indicating that its prompt was updated. In such instances, the design exploration application 130 determines each linked prompt volume (e.g., each prompt volume that is in its sphere of influence due to overlaps and/or direct links in a hierarchical relationship) that is linked to the prompt volume 222. When the design exploration application 130 determines that the prompt volume 222 received a message from a linked prompt volume, the design exploration application 130 proceeds to step 612. Otherwise, the design exploration application 130 determines that the prompt volume 222 did not receive a message from a linked prompt volume and proceeds to step 612.

At step 612, the design exploration application 130 updates design objects 144 within the prompt volume 222 in response to the message received from the linked prompt volume. In various embodiments, upon receiving a message from one or more linked prompt volumes indicating a change, the design exploration application 130 responds by updating one or more design objects 144 that are within the prompt volume. In some embodiments, the design exploration application 130 performs the update includes by transmitting a new multimodal prompt 260 based on the user changes. In such instances, the design exploration application 130 executes the applicable generative ML model 180, 190 on the multimodal prompt 260 to generate one or more updated design objects 270. The design exploration application 130 receives the updated design objects 270 and causes the prompt volume 222 to update by replacing the existing design object 144 with the updated design object 270.

At step 614, the design exploration application 130 generates a message indicating the updates made to the prompt. In various embodiments, upon completing one or more updates to design objects 144 in the prompt volume in response to a user change and/or a message from a linked prompt volume, the design exploration application 130 generates a message for the prompt volume 222 indicating each of the updates that the prompt volume 222 to the design objects 144.

At step 616, the design exploration application 130 transmits the generated message, In some embodiments, the design exploration application 130 transmits the generated message by identifying any other linked prompt volume that has not yet been updated based on the changes. For example, the design exploration application can identify any overlapping volumes and/or other prompt volumes further within the hierarchy. In some embodiments, the prompt volumes 222 operate on an execution cycle. In such instances, a given prompt volume 222 receives a message indicating a change during one cycle and propagates the message during a subsequent cycle.

### System Implementation

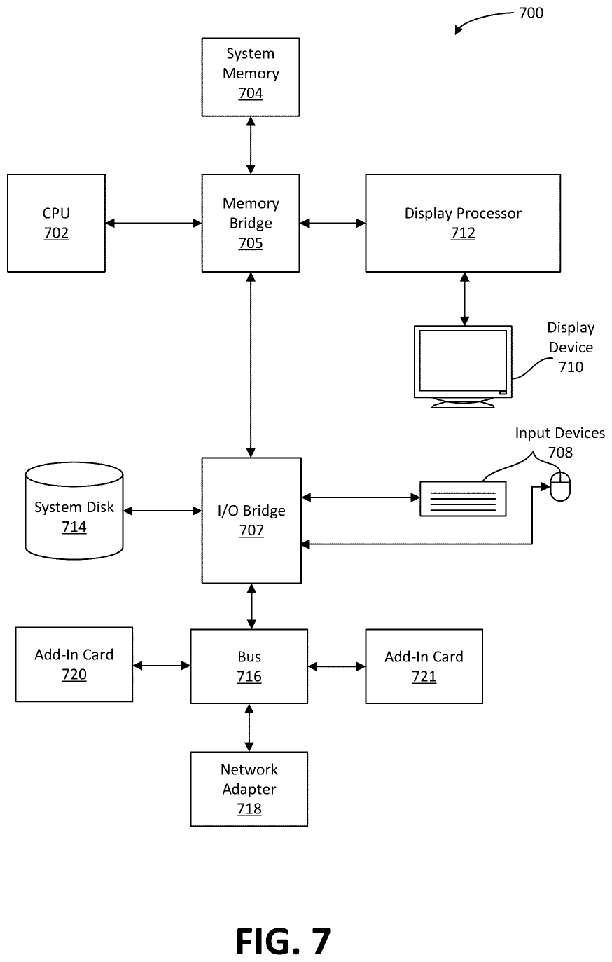

FIG. 7 depicts one architecture of a system 700 within which embodiments of the present disclosure may be implemented. This figure in no way limits or is intended to limit the scope of the present disclosure. In various implementations, system 700 may be an augmented reality, virtual reality, or mixed reality system or device, a personal computer, video game console, personal digital assistant, mobile phone, mobile device, or any other device suitable for practicing one or more embodiments of the present disclosure. Further, in various embodiments, any combination of two or more systems 700 may be coupled together to practice one or more aspects of the present disclosure.

As shown, system 700 includes a central processing unit (CPU) 702 and a system memory 704 communicating via a bus path that may include a memory bridge 705. CPU 702 includes one or more processing cores, and, in operation, CPU 702 is the master processor of system 700, controlling and coordinating operations of other system components. System memory 704 stores software applications and data for use by CPU 702. CPU 702 runs software applications and optionally an operating system. Memory bridge 705, which may be, e.g., a Northbridge chip, is connected via a bus or other communication path (e.g., a HyperTransport link) to an I/O (input/output) bridge 707. I/O bridge 707, which may be, e.g., a Southbridge chip, receives user input from one or more user input devices 708 (e.g., keyboard, mouse, joystick, digitizer tablets, touch pads, touch screens, still or video cameras, motion sensors, and/or microphones) and forwards the input to CPU 702 via memory bridge 705.

A display processor 712 is coupled to memory bridge 705 via a bus or other communication path (e.g., a PCI Express, Accelerated Graphics Port, or HyperTransport link); in one embodiment display processor 712 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 704.

Display processor 712 periodically delivers pixels to a display device 710 (e.g., a screen or conventional CRT, plasma, OLED, SED or LCD based monitor or television). Additionally, display processor 712 may output pixels to film recorders adapted to reproduce computer generated images on photographic film. Display processor 712 can provide display device 710 with an analog or digital signal. In various embodiments, one or more of the various graphical user interfaces set forth in Appendices A-J, attached hereto, are displayed to one or more users via display device 710, and the one or more users can input data into and receive visual output from those various graphical user interfaces.

A system disk 714 is also connected to I/O bridge 707 and may be configured to store content and applications and data for use by CPU 702 and display processor 712. System disk 714 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 716 provides connections between I/O bridge 707 and other components such as a network adapter 718 and various add-in cards 720 and 721. Network adapter 718 allows system 700 to communicate with other systems via an electronic communications network, and may include wired or wireless communication over local area networks and wide area networks such as the Internet.

Other components (not shown), including USB or other port connections, film recording devices, and the like, may also be connected to I/O bridge 707. For example, an audio processor may be used to generate analog or digital audio output from instructions and/or data provided by CPU 702, system memory 704, or system disk 714. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 712 incorporates circuitry optimized for graphics and video processing, including, for example, video output circuitry, and constitutes a graphics processing unit (GPU). In another embodiment, display processor 712 incorporates circuitry optimized for general purpose processing. In yet another embodiment, display processor 712 may be integrated with one or more other system elements, such as the memory bridge 705, CPU 702, and I/O bridge 707 to form a system on chip (SoC). In still further embodiments, display processor 712 is omitted and software executed by CPU 702 performs the functions of display processor 712.

Pixel data can be provided to display processor 712 directly from CPU 702. In some embodiments of the present disclosure, instructions and/or data representing a scene are provided to a render farm or a set of server computers, each similar to system 700, via network adapter 718 or system disk 714. The render farm generates one or more rendered images of the scene using the provided instructions and/or data. These rendered images may be stored on computer-readable media in a digital format and optionally returned to system 700 for display. Similarly, stereo image pairs processed by display processor 712 may be output to other systems for display, stored in system disk 714, or stored on computer-readable media in a digital format.

Alternatively, CPU 702 provides display processor 712 with data and/or instructions defining the desired output images, from which display processor 712 generates the pixel data of one or more output images, including characterizing and/or adjusting the offset between stereo image pairs. The data and/or instructions defining the desired output images can be stored in system memory 704 or graphics memory within display processor 712. In an embodiment, display processor 712 includes 3D rendering capabilities for generating pixel data for output images from instructions and data defining the geometry, lighting shading, texturing, motion, and/or camera parameters for a scene. Display processor 712 can further include one or more programmable execution units capable of executing shader programs, tone mapping programs, and the like.

Further, in other embodiments, CPU 702 or display processor 712 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 702, display processor 712, or one or more other processing devices or any combination of these different processors.

CPU 702, render farm, and/or display processor 712 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 700 may be a robot or robotic device and may include CPU 702 and/or other processing units or devices and system memory 704. In such embodiments, system 700 may or may not include other elements shown in FIG. 1. System memory 704 and/or other memory units or devices in system 700 may include instructions that, when executed, cause the robot or robotic device represented by system 700 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 704 is connected to CPU 702 directly rather than through a bridge, and other devices communicate with system memory 704 via memory bridge 705 and CPU 702. In other alternative topologies display processor 712 is connected to I/O bridge 707 or directly to CPU 702, rather than to memory bridge 705. In still other embodiments, I/O bridge 707 and memory bridge 705 might be integrated into a single chip. The particular components shown herein are optional; for instance, any number of add-in cards or peripheral devices might be supported. In some embodiments, switch 716 is eliminated, and network adapter 718 and add-in cards 720, 721 connect directly to I/O bridge 707.

In sum, the disclosed techniques can be used to generate designs for one or more 3D objects based on design intentions expressed by users using two or more modalities provided via a GUI. In various embodiments, a design exploration application displays a prompt space for a user to generate a prompt. The prompt space overlaps the design space, where a user can invoke a prompt anywhere in the design space. The design exploration application responds to a user input in the prompt space by generating a prompt that includes a prompt volume and a corresponding prompt definition. The prompt definition enables a user to specify design intent text and/or non-textual inputs, where the prompt definition guides the appearance and behavior of objects within the prompt volume. The prompt volume has a spatial position and boundaries that are defined via the textual definition, or via user input within the prompt space. The prompt volume includes a set of characteristics, including shape (e.g., spheres, cuboids, pyramids, irregular 3D shapes, etc.), weighted areas, weighted gradients, and linked prompt volumes. The linked prompted volumes include other overlapping prompt volumes and other prompt volumes linked in a hierarchy. The prompt volume exerts a sphere of influence within the defined boundaries such that modifications made to the associated prompt definition causes changes to design objects within the boundaries.

Upon generating the prompt, the design exploration application waits for user changes to the prompt definition or prompt volume. Upon identifying a user input that changes to the prompt definition or prompt volume, the design exploration application responds by updating one or more design objects that are within the prompt volume. In some embodiments, the update includes transmitting a new multimodal prompt based on the changes to a generative ML model that generates one or more updated design objects. In some embodiments, the prompt volume receives a message from one or more linked prompt volumes indicating a change. The design exploration application responds to the message from the linked prompt volume by updating the prompt volume based on the change. Upon completing the respective updates to the prompt volume, the design exploration application generates a message indicating each of the updates to the prompt volume made based on the user changes and the changes from the one or more linked prompt volumes. The design exploration application then causes the prompt volume to transmit the message. In some embodiments, the prompt volume transmits to any other linked prompt volume that has not yet been updated based on the changes, including any overlapping volumes and/or other prompt volumes further within the hierarchy.

At least one technical advantage of the disclosed techniques relative to the prior art is that the disclosed techniques enable generative systems to modify portions of a larger 3D design with greater precision. In that regard, the disclosed techniques enable users to define spatial volumes within a design space that constrain the scope of 3D objects generated by the generative design model. A design exploration application generating such spatial volumes within the larger design space enables a user to generate and modify specific aspects of a larger 3D design in a manner that ensures that the generative design model does not unintentionally modify other portions of the 3D design. Further, by using overlapping spatial volumes and/or a hierarchy of linked spatial volumes, the design exploration application enables users to modify multiple spatial volumes as a group in lieu of modifying each spatial volume separately, speeding the design process for the user. Accordingly, with the disclosed techniques, the design exploration application can generate 3D objects that are more responsive to the design intents of the user. The above technical advantages provide one or more technological improvements over prior art approaches.
1. In various embodiments, a computer-implemented method for generating a design object comprises generating a prompt within a design space generated by a design exploration application, where the prompt has a prompt definition that includes at least design intent text, and a prompt volume that occupies a portion of the design space and exerts a sphere of influence within the prompt volume, executing a trained machine learning (ML) model on the prompt to generate the design object, and displaying the design object within the prompt volume.
2. The computer-implemented method of clause 1, further comprising determining an update to at least one of the prompt definition or the prompt volume, and in response, modifying one or more design objects that occupy at least a portion of the prompt volume based on the update.
3. The computer-implemented method of clause 1 or 2, further comprising generating a second prompt having a second prompt volume that occupies a second portion of the design space and exerts a second sphere of influence within the prompt volume, and after modifying the one or more design objects that occupy the at least a portion of the prompt volume, modifying one or more second design objects that occupy at least a portion of the second prompt volume.
4. The computer-implemented method of any of clauses 1-3, where the prompt volume overlaps the second prompt volume.
5. The computer-implemented method of any of clauses 1-4, where the prompt volume is linked to at least the second prompt volume in a hierarchical relationship.
6. The computer-implemented method of any of clauses 1-5, where determining the update to the prompt volume comprises receiving a user input associated with at least one of moving the prompt volume, scaling the prompt volume, or reorienting the prompt volume.
7. The computer-implemented method of any of clauses 1-6, further comprising in response to determining the update to the prompt definition, executing the trained ML model on the update to the prompt definition to generate a second design object, where updating the one or more design objects that occupy at least a portion of the prompt volume comprises replacing the design object with the second design object within the prompt volume.
8. The computer-implemented method of any of clauses 1-7, further comprising generating a second prompt having a second prompt volume that occupies a second portion of the design space and exerts a second sphere of influence within the prompt volume, where a second design object is included within the second prompt volume and is not included in the prompt volume.
9. The computer-implemented method of any of clauses 1-8, further comprising executing a second trained ML model on a second prompt definition associated with second prompt volume to generate a second design object, and displaying the second design object within the prompt volume.
10. The computer-implemented method of any of clauses 1-9, where the trained ML model and the second trained ML model execute at least partially in parallel.
11. In various embodiments, one or more non-transitory computer-readable media include instructions that, when executed by one or more processors, cause the one or more processors to generate a design object by performing the steps of generating a prompt within a design space generated by a design exploration application, where the prompt has a prompt definition that includes at least design intent text, and a prompt volume that occupies a portion of the design space and exerts a sphere of influence within the prompt volume, executing a trained machine learning (ML) model on the prompt to generate the design object, and displaying the design object within the prompt volume.
12. The one or more non-transitory computer-readable media of clause 11, further comprising determining an update to at least one of the prompt definition or the prompt volume, and in response, modifying one or more design objects that occupy at least a portion of the prompt volume based on the update.
13. The one or more non-transitory computer-readable media of clause 11 or 12, further comprising generating a second prompt having a second prompt volume that occupies a second portion of the design space and exerts a second sphere of influence within the prompt volume, and after modifying the one or more design objects that occupy the at least a portion of the prompt volume, modifying one or more second design objects that occupy at least a portion of the second prompt volume.
14. The one or more non-transitory computer-readable media of any of clauses 11-13, where the prompt volume overlaps the second prompt volume.
15. The one or more non-transitory computer-readable media of any of clauses 11-14, where the prompt volume is linked to at least the second prompt volume in a hierarchical relationship.
16. The one or more non-transitory computer-readable media of any of clauses 11-15, where the one or more design objects are modified during a first execution cycle, and the one or more second design objects are modified during a second execution cycle.
17. The one or more non-transitory computer-readable media of any of clauses 11-16, further comprising instructions that, when executed by the one or more processors, cause the one or more processors to perform the step of in response to determining the update to the prompt definition, executing the trained ML model on the update to the prompt definition to generate a second design object, wherein updating one or more design objects that occupy at least a portion of the prompt volume comprises replacing the design object with the second design object within the prompt volume.
18. The one or more non-transitory computer-readable media of any of clauses 11-17, further comprising instructions that, when executed by the one or more processors, cause the one or more processors to perform the step of applying a weight to a portion of the sphere of influence.
19. The one or more non-transitory computer-readable media of any of clauses 11-18, further comprising instructions that, when executed by the one or more processors, cause the one or more processors to perform the steps of generating a second prompt having a second prompt volume that occupies a second portion of the design space and exerts a second sphere of influence within the prompt volume, wherein a second design object is included within the second prompt volume and is not included in the prompt volume, executing a second trained ML model on a second prompt definition associated with second prompt volume to generate a second design object, and displaying the second design object within the prompt volume.
20. In various embodiments, a system comprises one or more memories storing instructions, and one or more processors coupled to the one or more memories that, when executing the instructions, perform the steps of generating a prompt within a design space generated by a design exploration application, wherein the prompt has a prompt definition that includes at least design intent text, and a prompt volume that occupies a portion of the design space and exerts a sphere of influence within the prompt volume, executing a trained machine learning (ML) model on the prompt to generate a design object, and displaying the design object within the prompt volume.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more non-transitory computer readable medium or media may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine.

The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for generating a design object, the method comprising:
generating a prompt within a design space generated by a design exploration application, wherein the prompt has:
a prompt definition that includes at least design intent text, and
a prompt volume that occupies a portion of the design space and exerts a sphere of influence within the prompt volume;
executing a trained machine learning (ML) model on the prompt to generate the design object; and
displaying the design object within the prompt volume.

2. The computer-implemented method of claim 1, further comprising:
determining an update to at least one of the prompt definition or the prompt volume; and
in response, modifying one or more design objects that occupy at least a portion of the prompt volume based on the update.

3. The computer-implemented method of claim 2, further comprising:
generating a second prompt having a second prompt volume that occupies a second portion of the design space and exerts a second sphere of influence within the prompt volume; and
after modifying the one or more design objects that occupy the at least a portion of the prompt volume, modifying one or more second design objects that occupy at least a portion of the second prompt volume.

4. The computer-implemented method of claim 3, wherein the prompt volume overlaps the second prompt volume.

5. The computer-implemented method of claim 3, wherein the prompt volume is linked to at least the second prompt volume in a hierarchical relationship.

6. The computer-implemented method of claim 2, wherein determining the update to the prompt volume comprises receiving a user input associated with at least one of moving the prompt volume, scaling the prompt volume, or reorienting the prompt volume.

7. The computer-implemented method of claim 2, further comprising in response to determining the update to the prompt definition, executing the trained ML model on the update to the prompt definition to generate a second design object, wherein updating the one or more design objects that occupy at least a portion of the prompt volume comprises replacing the design object with the second design object within the prompt volume.

8. The computer-implemented method of claim 1, further comprising generating a second prompt having a second prompt volume that occupies a second portion of the design space and exerts a second sphere of influence within the prompt volume, wherein a second design object is included within the second prompt volume and is not included in the prompt volume.

9. The computer-implemented method of claim 8, further comprising:
executing a second trained ML model on a second prompt definition associated with second prompt volume to generate a second design object; and
displaying the second design object within the prompt volume.

10. The computer-implemented method of claim 9, wherein the trained ML model and the second trained ML model execute at least partially in parallel.

11. One or more non-transitory computer-readable media including instructions that, when executed by one or more processors, cause the one or more processors to generate a design object by performing the steps of:
generating a prompt within a design space generated by a design exploration application, wherein the prompt has:
a prompt definition that includes at least design intent text, and
a prompt volume that occupies a portion of the design space and exerts a sphere of influence within the prompt volume;
executing a trained machine learning (ML) model on the prompt to generate the design object; and
displaying the design object within the prompt volume.

12. The one or more non-transitory computer-readable media of claim 11, further comprising:
determining an update to at least one of the prompt definition or the prompt volume; and
in response, modifying one or more design objects that occupy at least a portion of the prompt volume based on the update.

13. The one or more non-transitory computer-readable media of claim 12, further comprising:
generating a second prompt having a second prompt volume that occupies a second portion of the design space and exerts a second sphere of influence within the prompt volume; and
after modifying the one or more design objects that occupy the at least a portion of the prompt volume, modifying one or more second design objects that occupy at least a portion of the second prompt volume.

14. The one or more non-transitory computer-readable media of claim 13, wherein the prompt volume overlaps the second prompt volume.

15. The one or more non-transitory computer-readable media of claim 13, wherein the prompt volume is linked to at least the second prompt volume in a hierarchical relationship.

16. The one or more non-transitory computer-readable media of claim 13, wherein the one or more design objects are modified during a first execution cycle, and the one or more second design objects are modified during a second execution cycle.

17. The one or more non-transitory computer-readable media of claim 12, further comprising instructions that, when executed by the one or more processors, cause the one or more processors to perform the step of in response to determining the update to the prompt definition, executing the trained ML model on the update to the prompt definition to generate a second design object, wherein updating one or more design objects that occupy at least a portion of the prompt volume comprises replacing the design object with the second design object within the prompt volume.

18. The one or more non-transitory computer-readable media of claim 11, further comprising instructions that, when executed by the one or more processors, cause the one or more processors to perform the step of applying a weight to a portion of the sphere of influence.

19. The one or more non-transitory computer-readable media of claim 11, further comprising instructions that, when executed by the one or more processors, cause the one or more processors to perform the steps of:
generating a second prompt having a second prompt volume that occupies a second portion of the design space and exerts a second sphere of influence within the prompt volume, wherein a second design object is included within the second prompt volume and is not included in the prompt volume;
executing a second trained ML model on a second prompt definition associated with second prompt volume to generate a second design object; and
displaying the second design object within the prompt volume.

20. A system comprising:
one or more memories storing instructions; and
one or more processors coupled to the one or more memories that, when executing the instructions, perform the steps of:
generating a prompt within a design space generated by a design exploration application, wherein the prompt has:
a prompt definition that includes at least design intent text, and
a prompt volume that occupies a portion of the design space and exerts a sphere of influence within the prompt volume;
executing a trained machine learning (ML) model on the prompt to generate a design object; and
displaying the design object within the prompt volume.
